(19) United States
(12) Patent Application Publication
(10) Pub. No.: US 2006/0245265 A1
(43) Pub. Date: Nov. 2, 2006

(54) Memory control system

(75) Inventor: Kyung Ah Jeong, Dongjak-ku (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: C&S Technology Co., Ltd., Songpa-ku (KR)

(21) Appl. No.: 11/264,873

(22) Filed: Nov. 2, 2005

(30) Foreign Application Priority Data
Apr. 29, 2005 (KR) 10-2005-0035807

(51) Int. Cl. G11C 7/10; G06F 12/00

(52) U.S. Cl. 365/189.01; 711/100

(57) ABSTRACT

The memory control system includes a memory unit, bus master(s), arbiter, and memory controller. The bus masters output bus use request signals, block mode signals, block information, and drive information for data and outputs data corresponding to block/receive read-out data. The arbiter receives request signals and drive information and outputs a master selection signal used to select a bus master to which access is permitted and the drive signal input from the selected bus master. The bus master selection unit receives block mode signals, block information and data corresponding to the bus masters and outputs the block mode signal, block information and bus master data selected according to the master selection signal. The memory controller receives drive information from the arbiter, block mode signal, and block information from the selection unit, and allows data corresponding to respective line block groups to be sequentially-stored in/read out from respective banks.

### BACKGROUND OF THE INVENTION

1. Field of the Invention

The present invention relates generally to a memory control system and, more particularly, to a memory control system including an arbiter.

2. Description of the Related Art

Mobile communication equipment, including a recent Digital Multimedia Broadcasting (DMB) receiver, processes various multimedia signals, which are received from the earth or a satellite, in a digital manner and compresses image data to process the image data at high speed.

The compression of image data is performed through the detection of the motion information of the images that constitute respective frames. A general method of compressing image data using motion information as described above is performed as described below.

First, the difference elements between a reference image block included in a current frame and comparative image blocks included in previous frames are calculated, and a comparative image block that allows the absolute value of a calculated difference element to be minimized is selected. A motion vector is determined based on the difference in distance between the selected comparative image block and the reference image block and the direction of movement.

Next, the difference element between a image block, which is obtained by moving a image block in the search region of the previous frame by the motion vector, and the reference image block of the current frame is calculated, and an error signal for compensating the current frame with the previous frame is output. When compression is performed using such an error signal, a specific frame can be restored using the error signal during decoding, so that a compression rate is increased.

In the above-described process, image data corresponding to the current frame, the previous frame, the reference image block and the comparative image block are stored in memory, such as Synchronous Dynamic Random Access Memory (SDRAM).

In that case, the image data are stored in the memory by the following general method.

FIG. 1 illustrates a general method of storing image data in memory. The general image data storage method causes the positions of the starting addresses of the image lines of image data constituting a single frame to be identical. That is, the starting positions of image data constituting a first image line Bank0,RAS0 to a sixteenth image line Bank0,RAS15 are identical to each other. When image data are stored in the above-described manner, the starting positions of image lines constituting an image block are identical to each other.

In this case, when a memory map is set up such that the bank addresses of respective image lines can have different values, more efficient access can be gained by a bank interleaving method using the characteristics of SDRAM.

In order to use such a bank interleaving method, a structure for exchanging additional signals is required, in addition to a general Advanced Microcontroller Bus Architecture (AMBA) interface. For this reason, a memory control system, such as Korean Unexamined Pat. Pub. No. 10-2004-0100631, was proposed.

FIG. 2 is a block diagram of a conventional memory control system. FIG. 3a is a timing diagram for the arbitration of data access between a bus master and slaves in the conventional memory control system, and FIG. 3b is a timing diagram for the bank interleaving of the conventional memory control system.

As illustrated in FIGS. 2 and 3a, a bus master1 110a and a bus master2 110b simultaneously output signals HBUSREQ1 and HBUSREQ2 requesting access to synchronous DRAM 140 to an arbiter 120. Accordingly, the arbiter 120 simultaneously output approval signals HGRANT1 and HGRANT2 to the bus masterl 110a and the bus master2 110b, and the bus master1 110a and the bus master2 110b are determined to have bus ownership.

Thereafter, the bus masterl 110a and the bus master2 110b output address information HADDR1 and HADDR2 to the arbiter 120. The arbiter 120 assigns substantial bus ownership to the bus masterl 110a attempting to access a bank that belongs to banks to which access has been requested, and that is prepared for access. Accordingly, an SDRAM controller 130 reads out data DATA1 to DATA4 and outputs the data DATA1 to DATA4 to the bus masterl 110a, and, thereafter, reads out data DATA5 to DATA8 and outputs the data DATA5 to DATA8 to the bus master2 110b.

As shown in FIG. 3b, the conventional memory control system performs a Row Address Strobe (RAS) command RAS0 and a Column Address Strobe (CAS) command CAS0 on a first bank BA0 and, thereafter, performs a RAS command RAS1 and a CAS command CAS1 on a subsequent bank BA1. Furthermore, since the timing of the commands is set to be suitable for the characteristics of SDRAM 140, that is, time of RAS-to-CAS Delay (tRCD) and time of CAS Latency (tCL), unnecessary clock consumption is eliminated during the readout of data, so that data B0D0 to B0D3 stored in the first bank are read out and data B1D0 to B1D3 stored in the second bank are then read out.

However, the conventional memory control system can prevent unnecessary clock consumption only when four or more pieces of data are read out from one bank. In order to access three or fewer pieces of data, a RAS command must be performed on the second bank Bank1 142b between a RAS command and a CAS command performed on the first bank Bank0 142a, so that a problem arises in that the structure of the SDRAM controller 130 is complicated.

That is, as illustrated in FIG. 3b, tRCD and tCL are determined, so that, in order to access three or fewer pieces of data without clock consumption, a RAS command must be performed on a subsequent band between a RAS command and a CAS command performed on one bank. For example, since the SDRAM controller 130 must process the RAS command for access to the second bank Bank1 between the RAS command and the CAS command for access to the first bank Bank0, the SDRAM controller 130 must separately calculate tRCD for access to the first bank Bank0 and tRCD for access to the second bank Bank1 so as to check whether the tRCDs are guaranteed.

Due to the separate calculation for the check on a guarantee of tRCDs, the amount of calculation that must be performed by the SDRAM controller 130 increases, so that the structure of the SDRAM controller 130 is complicated. Furthermore, another problem arises in that, when tRCDs are not guaranteed, the conventional memory control system must be provided with an additional circuit for guaranteeing tRCDs. Since the arbiter 120 of the conventional memory control system must also and simultaneously activate the access of many bus masters while monitoring the access state of the SDRAM controller 130, the circuit of the arbiter 120 becomes more complicated and the probability of the occurrence of errors becomes higher as the number of bus masters becomes larger.

As the size of the image block of FIG. 1 becomes smaller, the above-described problems of the conventional memory control system become prominent. In particular, a compression method, such as H.264, uses a 2×2 size image block, so that the problems of the conventional memory control system are more serious.

Meanwhile, it is impossible for the conventional memory control system to make single access that connects two or more banks. For example, when one bus master wants access to a region ranging from the rear address region of the first bank Bank0 142a to the front address region of the second bank Bank1 142b, the request of the bus master for access to the second bank Bank1 142b must be separately made after access to the rear address region of the first bank Bank0 142a has been made. Accordingly, when the master makes access, unnecessary time delay occurs and the circuit of the bus master is complicated.

Furthermore, in a general data interface, an address having a sequence suitable for bank interleaving is not generated. In particular, access to a plurality of image lines is required at one time during image processing, so that it is common for a single master to request access to a plurality of image lines at one time in a structure requiring bank interleaving. However, the conventional memory control system is problematic in that it is difficult for a single master to request access to a plurality of image lines at one time.

### SUMMARY OF THE INVENTION

Accordingly, the present invention has been made keeping in mind the above problems occurring in the prior art, and an object of the present invention is to provide a memory control system that is less influenced by the size of an image block in a process of compressing image data, incurs no clock consumption, and has a simple structure and a simple calculation procedure.

In order to accomplish the above object, the present invention provides a memory control system, including a) a memory unit including a plurality of banks; b) one or more bus masters for outputting bus use request signals, block mode signals, block information and drive information for data and, accordingly, outputting data corresponding to a block or receiving read-out data; c) an arbiter for receiving the bus use request signals and the drive information and outputting a master selection signal used to select a bus master to which access is permitted and the drive signal input from the selected bus master; d) a bus master selection unit for receiving the block mode signals, the block information and the data corresponding to data from the bus masters and outputting the block mode signal, block information and data of the bus master selected according to the master selection signal; and e) a memory controller for receiving the drive information from the arbiter and the block mode signal and the block information from the bus master selection unit and allowing data corresponding to the respective line groups of the block to be sequentially stored in or read out from the respective banks.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a diagram illustrating a conventional method of storing image data in memory;

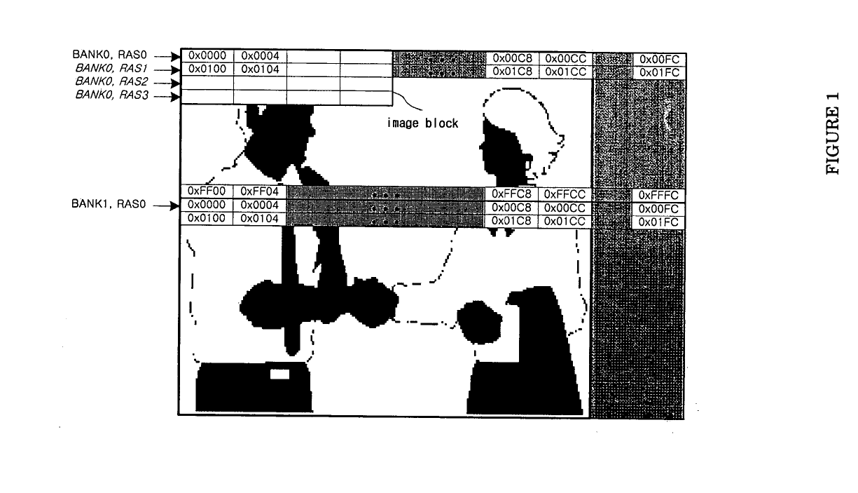

FIG. 2 is a block diagram of the conventional memory control system;

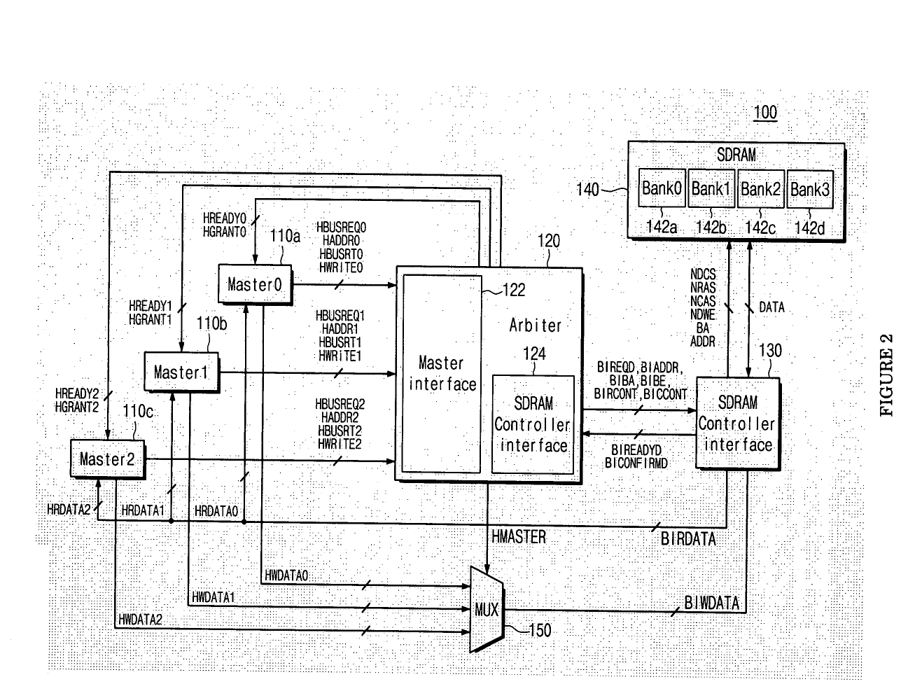

FIG. 3a is a timing diagram for the arbitration of data access between a bus master and slaves in the conventional memory control system;

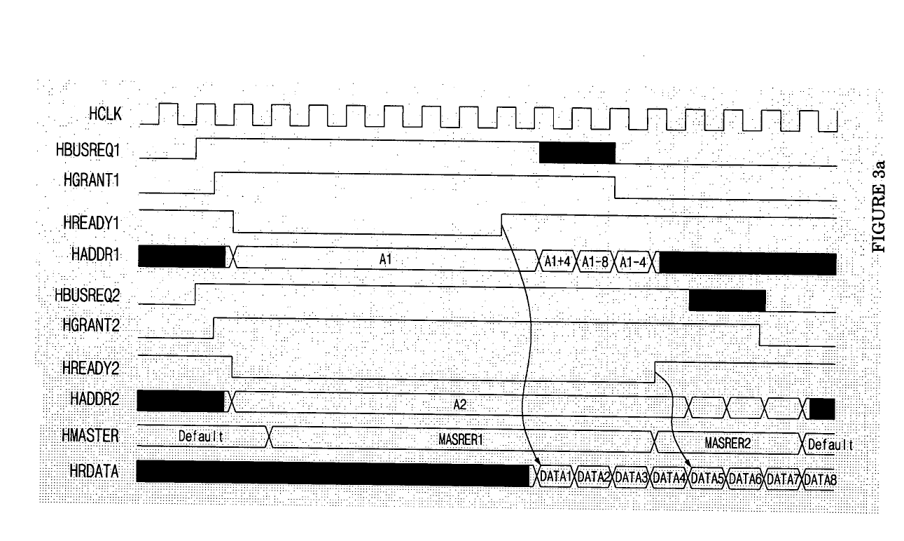

FIG. 3b is a timing diagram for the bank interleaving of the conventional memory control system;

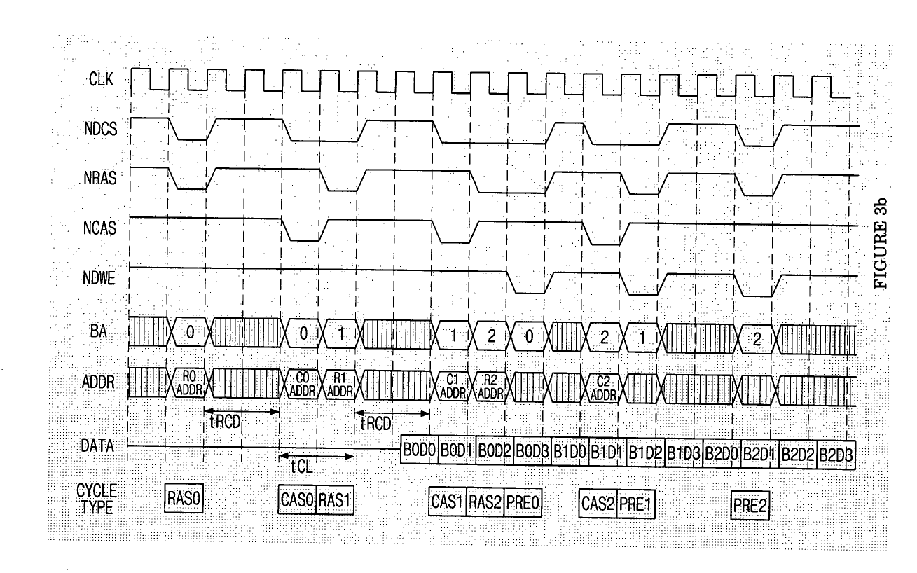

FIG. 4 is a diagram illustrating the concept of the operation of a memory control system according to the present invention;

FIG. 5 is a block diagram of a memory control system according to the present invention;

FIG. 6 is an address map for the access to image data stored according to present invention;

FIG. 7 is a schematic diagram illustrating image data read out or stored according to the operation of the memory control system of the present invention;

FIG. 8 is a diagram illustrating image data corresponding to the image block of FIG. 7; and

FIG. 9 is a command and address input timing diagram for the access to the image data of FIG. 8 in accordance with the operation of the memory control system of the present invention.

### DESCRIPTION OF THE PREFERRED EMBODIMENTS

Reference now should be made to the drawings, in which the same reference numerals are used throughout the different drawings to designate the same or similar components.

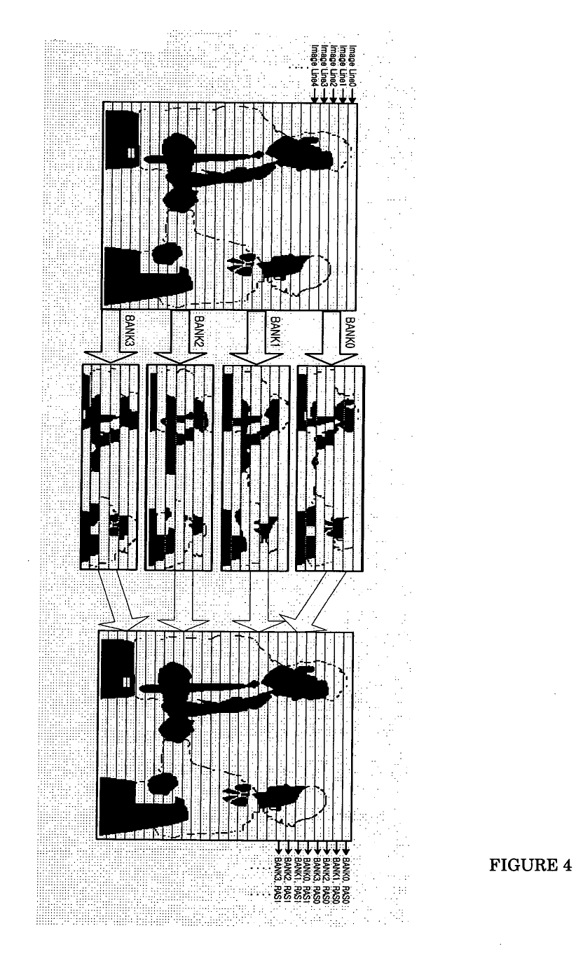

FIG. 4 illustrates the concept of the operation of a memory control system according to the present invention. A one-frame image is shown on the left side of FIG. 4, the state of image data stored in memory by the operation of the memory control system of the present invention is shown at the center of FIG. 4, and image data that have been stored in the memory and are read by the operation of the memory control system of the present invention are shown on the right side of FIG. 4.

Respective pieces of image data corresponding to respective image lines shown on the left side of FIG. 4 are stored in different banks, as shown at the center of FIG. 4. That is, image data corresponding to the first image line Image Line0 of a frame are stored in a region corresponding to the first row address RAS0 of a first bank Bank0. Image data corresponding to the second image line Image Line1 of the frame are stored in a region corresponding to the first row address RAS0 of a second bank Bank1. Image data corresponding to the third image line Image Line2 of the frame are stored in a region corresponding to the first row address RAS0 of a third bank Bank2. Image data corresponding to the fourth image line Image Line3 of the frame are stored in a region corresponding to the first row address RAS0 of a fourth bank BANK3. Furthermore, image data corresponding to the fifth image line Image Line4 of the frame are stored in a region corresponding to the second row address RAS1 of the first bank BANK0. Thereafter, the above-described process is repeated.

Although, in the above-described process, respective image lines are sequentially stored in respective banks, it is possible to sequentially store respective image line groups each composed of one or more image lines in respective banks if memory is composed of a plurality of banks. For example, image data corresponding to the first and second image lines of a frame are stored in the first bank BANK0. Image data corresponding to the third and fourth lines of the frame are stored in the second bank BANK1. Image data corresponding to the fifth and sixth lines of the frame are stored in the third bank BANK2. Image data corresponding to the seventh and eighth lines of the frame are stored in the fourth bank BANK3. Image data corresponding to the ninth and tenth lines of the frame are stored in the first bank BANK0. This process is repeated.

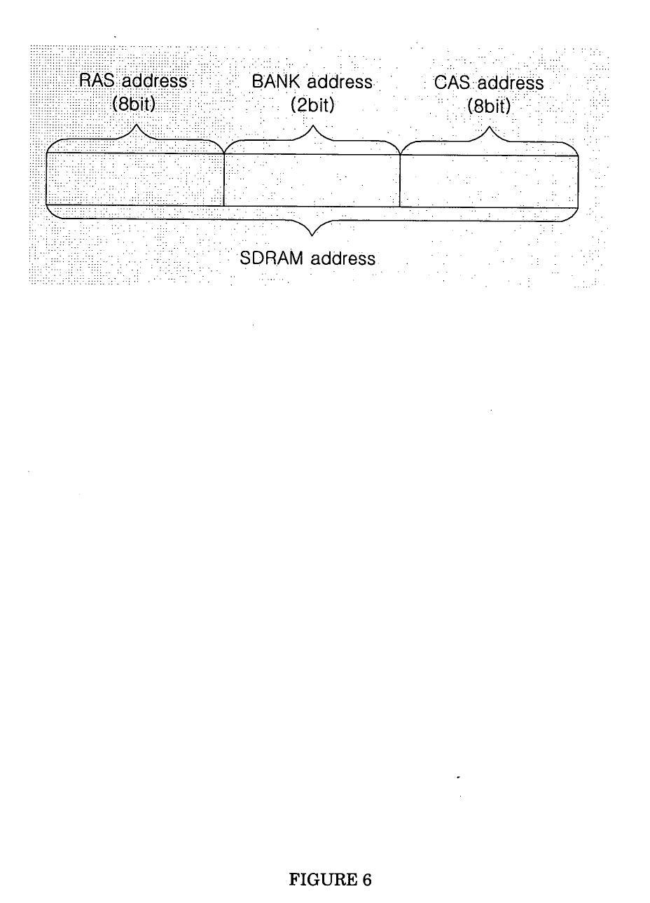

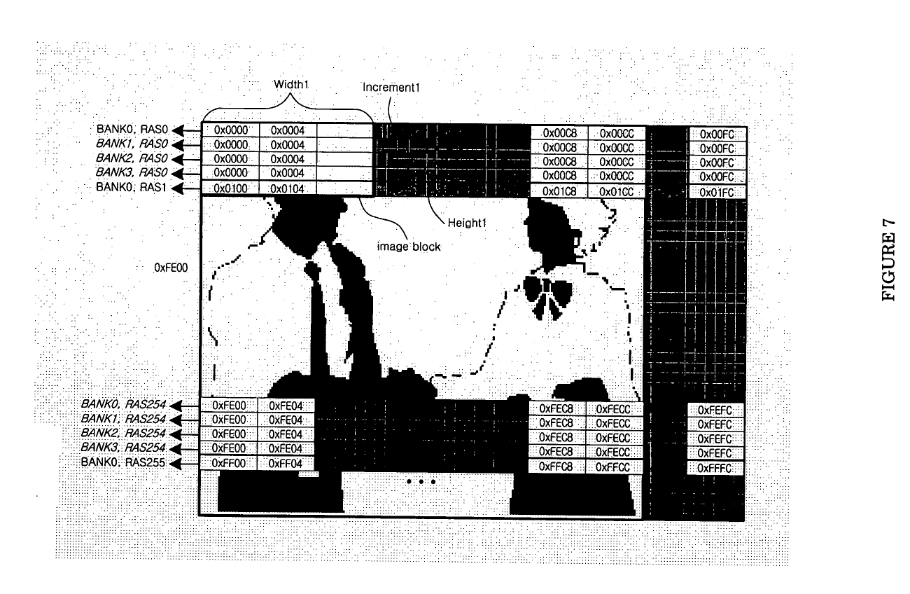

The above-described operation is applied to the access to image blocks that are used to compress image data in the same manner. A description thereof is made with reference to FIGS. 6 and 7 below.

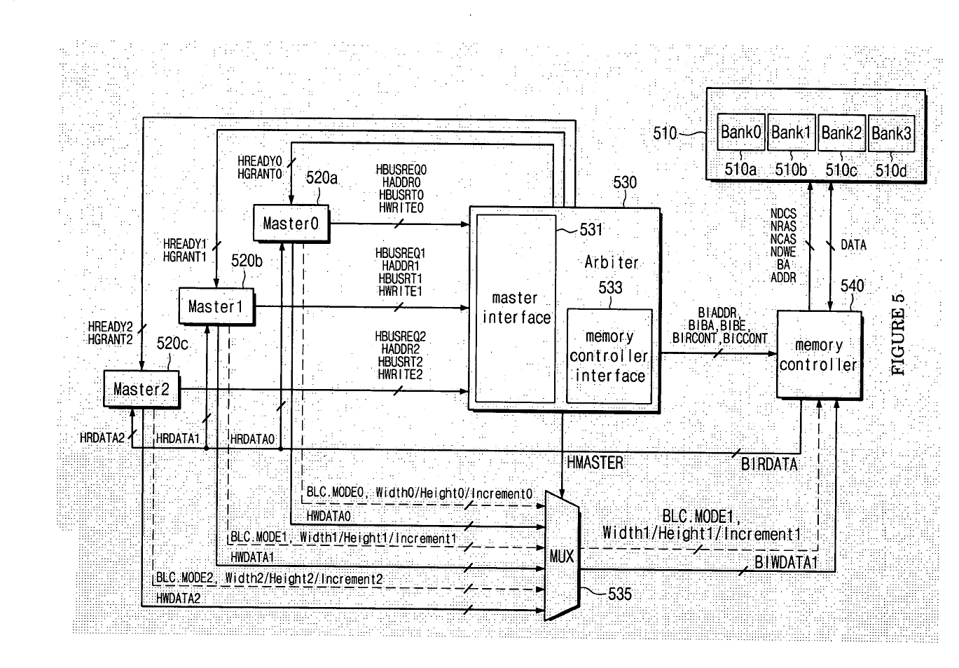

FIG. 5 is a block diagram of the memory control system according to the present invention. As shown in FIG. 5, the memory control system according to the present invention includes a memory unit 510, a plurality of bus masters 520a, 520b and 520c, an arbiter 530 and a memory controller 540.

The memory unit 510 includes a plurality of banks 510a, 510b, 510c and 510d, and stores data corresponding to image line groups constituting an image block. In this case, each of the image line groups is composed of one or more image lines.

The bus masters 520a, 520b and 520c output bus use request signals HBUSREQ0, HBUSREQ1 and HBUSREQ2, block mode signals BLC.MODE0, BLC.MODE1 and BLC.MODE2, image block information Width0 to Width2, Height0 to Height2 and Increment0 to Increment2, data corresponding to image blocks HWDATA0 to HWDATA2 and drive information about the data of image blocks HADDR0 to HADDR2, HBUSRT0 to HBUSRT2 and HWRITE0 to HWRITE2, and then output image data for storage or receive read-out image data. The drive information includes address information HADDR1 to HADDR3 and control information HBURST1 to HBURST3 and HWRITE1 to HWRITE3. The image block information includes the widths of image blocks Width0 to Width2, the heights of image blocks Height0 to Height2 and the address increments of image line groups, that is, image line increments Increment0 to Increment2. In this case, the image line increments mean physical address increments. For example, if the starting address of an nth image line is 0x400 and the starting address of an (n+1)th image line is 0x800, an image line increment is 0x400. The starting address of an (n+2)th image line is automatically calculated as 0xC00 based on the image line increment.

The arbiter 530 receives bus use request signals HBUSREQ0, HBUSREQ1 and HBUSREQ2 and drive information about image blocks from the bus masters 520a, 520b and 520c, selects a bus master that will allow access, and outputs a master selection signal HMASTER and the drive information input from the bus master.

A bus master selection unit 535 includes a multiplexer MUX, receives block mode signals BLC.MODE0 to BLC.MODE2, image data HWDATA0 to HWDATA2 corresponding to image blocks and image block information Width0 to Width2, Height0 to Height2 and Increment0 to Increment2 from one or more bus masters 520a, 520b and 520c, and outputs the block mode signal BLC.MODE1 of the bus master that is selected according to the master selection signal HMASTER output from the arbiter 530, image block information Width1, Height1 and Increment1 and image data BIWDATA1 corresponding to an image block.

The memory controller 540 receives drive information from the arbiter 530 and block mode signals BLC.MODE0, BLC.MODE1 and BLC.MODE2 from the bus master selection unit 535, and controls the memory unit 510 so that the image line groups of an image block corresponding to the drive information and the block mode signals are sequentially stored in and read out from the regions of respective banks having the same row addresses.

With reference to the drawings, the operation of the memory control system according to the present invention is described in detail.

Each bus master 520a, 520b or 520c outputs a signal HBUSREQ0, HBUSREQ1 or HBUSREQ2s requesting access to the banks 510a, 510b, 510c and 510d of the memory unit 510 to the arbiter 530, and outputs data HWDATA0, HWDATA1 and HWDATA2 corresponding to image blocks, block mode signals BLC.MODE0, BLC.MODE1 and BLC.MODE2 and image block information Width0 to Width2, Height0 to Height2 and Increment0 to Increment2 to the bus master selection unit 535.

The arbiter 530 selects one from among the bus masters 520a, 520b and 520c, outputs an approval signal HGRANT0, HGRANT1 or HGRANT2 to the selected bus master, and outputs a master selection signal HMASTER to the bus master selection unit 535. If the bus masterl 520b in charge of display is selected, the bus masterl 520b outputs drive information, that is, address information HADDR1 and control information HBURST1 and HWRITE1, to the arbiter 530.

Furthermore, the arbiter 530 outputs a data process preparation request BIREQD to the memory controller 540. When the banks are prepared for access, the arbiter 530 receives address information BIADDR and control information BIBA, BIBE, BIRCONT and BICCONT corresponding to the drive information and outputs the information to a memory controller interface 533.

Furthermore, the arbiter 530 outputs a preparation signal HREADY1 to allow the bus master1 520b to use a system bus, and makes arbitration such that data are transmitted between the bus master1 520b and the banks 510a, 510b, 510c and 510d.

Meanwhile, the bus master selection unit 535 outputs the data HWDATA1 corresponding to the image block, the block mode signal BLC.MODE1 and the image block information Width1, Height1 and Increment1, which are transmitted from the bus masterl 520b, to the memory controller 540 in response to the master selection signal HMASTER input from the arbiter 530.

The memory controller 540 having received the block mode signal BLC.MODE1 and the image block information Width1, Height1 and Increment1 performs an access process according to the received address information BIADDR.

At that time, the address map of the address information BIADDR is shown in FIG. 6. As shown in FIG. 6, a bank address is assigned to bits lower than those of the row address for the operation of the memory control system of the present invention. Accordingly, as a column address increases, image data are stored in the region of a specific row line of a specific bank of the memory. Thereafter, the bank address increases and the row address are maintained without change, so that image data are stored in a specific line of a subsequent bank.

In conformity with such an address map, the memory controller 540 writes or reads out data DATA to and from the memory unit 510 according to the address ADDR and the control information NDCS, NRAS, NCAS, NDWE and BA.

FIG. 7 schematically illustrates image data read out or stored according to the operation of the memory control system of the present invention. As shown in FIG. 7, the image lines of an image block having a width Width1, a height Height1 and an image line increment Increment1 are sequentially stored in and read out from respective banks by the memory controller 540.

That is, the memory controller 540 stores image data in the region of a specific row line RAS0 of a specific bank BANK0 while increasing a column address from 0x0000 to 0x00CC according to the address map of FIG. 6. Thereafter, the memory controller 540 designates a subsequent bank BANK1 by increasing the bank address and maintains the row address without change. Accordingly, image data are stored in a region corresponding to BANK1, RAS0 while the column address is increased from 0x0000 to 0x00CC. Thereafter, the image data corresponding to the image block are stored by the repetition of the above-described process.

When the memory controller 540 accesses image data corresponding to a specific image line (nth), the memory controller 540 calculates the address of the specific line (nth) by adding an image line increment to the address of a previous image line ((n−1)th).

When the bank address is increased prior to the row address after the column address has been increased by the operation of the memory control system of the present invention, the memory can be more efficiently managed. Furthermore, since the memory control system of the present invention calculates the address using the image line increment Increment, the amount of calculation can be considerably reduced.

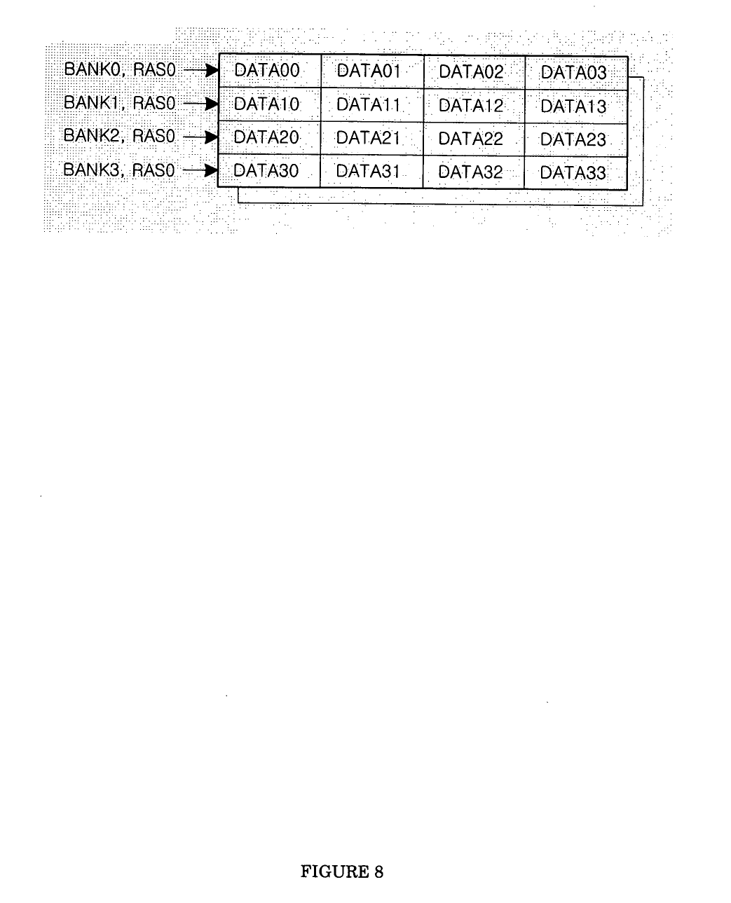

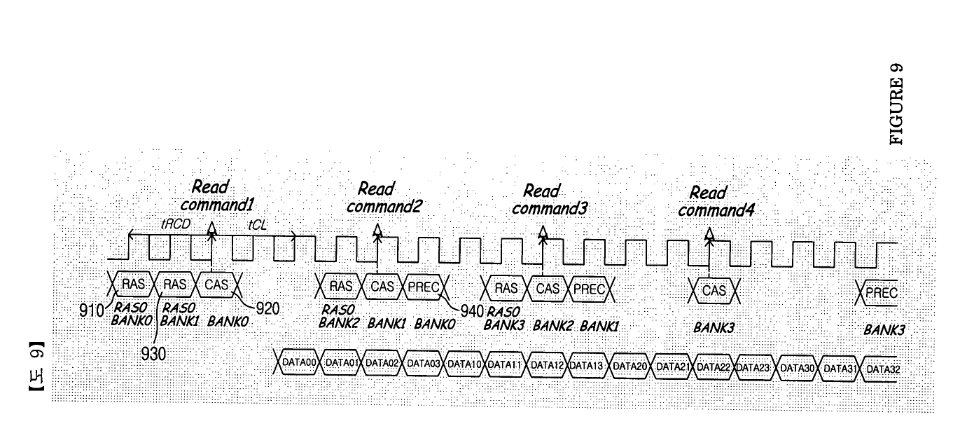

FIG. 8 illustrates image data corresponding to the image block of FIG. 7, and FIG. 9 is a command and address input timing diagram for the access to the image data of FIG. 8 in accordance with the operation of the memory control system of the present invention.

When a RAS signal 910 for designating the first row address RAS0 of the first bank BANK0 is input for the access to data DATA00 to DATA03, a read command Read command1 and a CAS signal 920 are input after a clock corresponding to the tRCD.

In that case, a RAS signal 930 for designating the first row address RAS0 of the second bank BANK1 is input for the access to data DATA10 to DATA13 during the tRCD between the RAS signal 910 and the CAS signal 920.

The reason why the above-described input of signals is possible is because it is generally possible to separately control respective banks that constitute memory.

Accordingly, when respective image lines are sequentially stored in respective banks as in the present invention, the input of the RAS signal for the access to a specific image line stored in a subsequent bank can be performed during the tRCD for the access to a specific image line stored in one bank.

Access can start without addition clock consumption because the RAS signal 930 for the second bank BANK1 has been input between the RAS signal 910 and CAS signal 920 for the first bank BANK0 at the time when a read command Read command2 for the access to data DATA10 to DATA13 stored in the second bank BANK1 must be transmitted, that is, before the CAS signal for the second bank BANK1 is input.

In the same manner, the precharge 940 for the first bank BANK0 can be performed at an unoccupied clock during the read operation for the second bank BANK1, so that the clock for the precharge 940 does not need to be actually consumed. That is, since precharge commands must also be performed on respective banks, precharge is performed on a specific bank when the access to a certain bank has been completed and the access to a subsequent bank is performed. After the access to all the banks has been completed, precharge is performed all the banks.

In the case where there is no clock in reserve for precharge because the width of the image block is very small, the memory controller 540 can prevent clock consumption for precharge in such a way as to automatically precharge a certain bank after image data corresponding to an image line group have been stored in or read out from the bank.

The above-described process is performed on the second bank BANK1 to the fourth bank BANK3 in the same manner. That is, a RAS signal for the access to image data corresponding to a specific line of a subsequent bank is input between the RAS signal and CAS signal for the access to image data corresponding to a specific line of one bank. Furthermore, the precharge for the one bank is performed during the access to the subsequent bank.

At that time, the memory control system of the present invention can store or read out respective image lines constituting an image block in or from the same row addresses RAS0 of respective banks BANK0, BANK1, BANK2 and BANK3 as shown in FIGS. 7 and 8, or store or read out respective image lines in or from the different row addresses of respective banks.

In summary, it can be state that a command to access image data corresponding to a specific line of a subsequent bank is executed while the access to image data corresponding to a specific line of one bank. Through the above-described process, the access to the data DATA00 to DATA03 of FIG. 9 and the access to the data DATA10 to DATA13 of FIG. 9 are successively performed, so that unnecessary clock consumption can be prevented.

A problem arises in that the access of the conventional memory control system to data, the number of the pieces of which is smaller than a certain number, using bank interleaving causes the complexity of the system. In contrast, in the memory control system of the present invention, the type of access is previously determined by a block mode signal and image block information output from a bus master requesting the access, and information about the type of access is transmitted to the memory controller, and the respective image lines of an image block are sequentially stored in regions corresponding to the same row addresses of respective banks, so that a RAS command and a CAS command for a subsequent bank can be executed between a RAS command and a CAS command for the one bank and precharge can be performed during a read operation for the subsequent bank.

As a result, the memory control system of the present invention has a simple structure, is less influenced by the size of an image block to be accessed and can prevent unnecessary clock consumption.

Furthermore, the memory access for general image process requires the access to a plurality of lines or the access to a plurality of banks at one time, but it is impossible for the conventional memory control system to perform access two or more times at one time. However, the memory control system of the present invention can solve the problem because the system sequentially stores the data of respective lines constituting an image block in the addresses of respective banks.

Meanwhile, the memory control system of the present invention can be applied to the processing of general data as well as the processing of image data.

As described above, the memory control system of the present invention is less influenced by the size of an image block, has no unnecessary clock consumption and simplifies a calculation procedure, without the change of a structure.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A memory control system, comprising:
a memory unit including a plurality of banks;
one or more bus masters for outputting bus use request signals, block mode signals, block information and drive information for data and, accordingly, outputting data corresponding to a block or receiving read-out data;
an arbiter for receiving the bus use request signals and the drive information and outputting a master selection signal used to select a bus master to which access is permitted and the drive signal input from the selected bus master;
a bus master selection unit for receiving the block mode signals, the block information and the data corresponding to data from the bus masters and outputting the block mode signal, block information and data of the bus master selected according to the master selection signal; and
a memory controller for receiving the drive information from the arbiter and the block mode signal and the block information from the bus master selection unit and allowing data corresponding to respective line groups of the block to be sequentially stored in or read out from the respective banks.

2. The memory control system as set forth in claim 1, wherein the drive information comprises address information and control information.

3. The memory control system as set forth in claim 1, wherein the block information comprises information about a width of the block, information about a height of the block and row address increments of the line groups.

4. The memory control system as set forth in claim 1, wherein each of the line groups comprises one or two lines.

5. The memory control system as set forth in claim 2, wherein an address map of the address information assigns bank addresses to bits lower than those of row addresses.

6. The memory control system as set forth in claim 1, wherein the memory controller allows the data corresponding to the line groups to be sequentially stored in or read out from regions corresponding to same row addresses of the respective bands.

7. The memory control system as set forth in claim 1, wherein the memory controller outputs a Row Address Strobe (RAS) command for access to a subsequent bank between a RAS command and a Column Address Strobe (CAS) command for access to a specific bank.

8. The memory control system as set forth in claim 1, wherein the memory controller performs preliminary charging on a specific bank during access to a subsequent bank.

9. The memory control system as set forth in claim 1, wherein the memory controller performs preliminary charging on all the banks after access to all the banks has been completed.

10. The memory control system as set forth in claim 1, wherein the memory controller stores or reads out the data corresponding to the line groups in or from a certain bank according to a set mode and, thereafter, performs preliminary charging on the bank.

11. The memory control system as set forth in claim 3, wherein the memory controller calculates an address of a subsequent line group by adding a row address increment to an address of a previous line group.
